(19) United States
(12) Patent Application Publication
(10) Pub. No.: US 2003/0188683 A1
(43) Pub. Date: Oct. 9, 2003

(54) UV reactor for transport polymerization

(75) Inventors: Chung J. Lee, Fremont, CA (US); Oanh Nguyen, Union City, CA (US); Atul Kumar, Fremont, CA (US)

Correspondence Address: JACKSON WALKER LLP, 2435 NORTH CENTRAL EXPRESSWAY, SUITE 600, RICHARDSON, TX, 75080, US

(73) Assignee: DIELECTRIC SYSTEMS, INC., Fremont, CA

(21) Appl. No.: 10/115,879

(22) Filed: Apr. 4, 2002

(51) Int. Cl. C23F 1/00; C23C 14/00

(52) U.S. Cl. 118/50.1; 156/345.5

(57) ABSTRACT

An improved reactor to facilitate new precursor chemistries and transport polymerization processes that are useful for preparations of low ε (dielectric constant) films. An improved TP Reactor that consists of UV source and a fractionation device for chemicals is provided to generate useful reactive intermediates from precursors. The reactor is useful for the deposition system.

### BACKGROUND

This invention is related to a semiconductor equipment that is useful for the fabrication of integrated circuits (“IC”). In particular, this invention is related to an ultra violet (“UV reactor”) that is useful for transport polymerization of precursor and deposition of low dielectric (“ε”) thin films in IC. The invention consists of an UV energy source for the UV reactor, and a fractionation device for separation of useful reactive intermediates that are derived from precursors. Furthermore, a vapor flow controller (“VFC”) attached to the UV reactor allows precision control of feed rate for precursors and film deposition rate. Because the UV reactor does not generate excessive heat during operation as other prior art reactors, a reactor cleaning subsystem that used in thermal reactor is not needed, thus simplifies the reactor design.

During the construction of IC's with shrinking device geometries, an increase in capacitance, mainly on the same layer of interconnects can result in unacceptable crosstalk and interconnect or RC delay. This RC delay has become a serious problem for IC's with feature size of less than 0.18 μm. Thus, the dielectric constant of current insulation materials from which IC's are constructed must be decreased to meet the needs for fabrication of future IC's. In addition to dielectric and conducting layers, the “barrier layer” may include metals such as Ti, Ta, W, and Co and their nitrides and silicides, such as TiN, TaN, TaSixNy, TiSixNy, WNx, CoNx and CoSiNx. Ta is currently the most useful barrier layer material for the fabrication of IC's that currently use copper as conductor. The “cap-layer” or “etch-stop-layer” normally consists of dielectric materials such as SiC, SiN, SiON, SiyOx and its fluorinated silicon oxide (“FSG”) and SiCH. Thus, the new dielectric materials must also withstand many other manufacturing processes following their deposition onto a substrate.

Currently, there are two groups of low E dielectric materials, which include an inorganic group exemplified by SiO₂, and its F- and C & H modified derivatives respectively called FSG and SiCOH and an organic group exemplified by an aromatic polymer called SiLK supplied by Dow Chemical Company. The inorganic and polymer thin films are prepared respectively by Chemical Vapor Deposition (“CVD”) and Spin-On processes. The current dielectric materials used in the manufacturing of the IC's have already proven to be inadequate in several ways for their continued usage in production of future IC's. For example, all of the above listed materials have high dielectric constant (≧2.7) and marginal Young's Modulus (2.5 to 3.5 GPa).

Although not wanting to be bound by theory, whereas all conventional CVD processes have failed to make useful Ta-compatible thin films with a ε<2.7, transport polymerization (“TM”) may become a primary approach for making useful low k films that are practical for fabrications of future IC's. Some of the important chemistries and mechanisms involved during TP has been reviewed previously (Chung Lee, “Transport Polymerization of Gaseous Intermediates and Polymer Crystals Growth” J. Macromol. Sci-Rev. Macromol. Chem., C16 (1), 79-127 (1977-78), pp79-127 and are hereby incorporated by reference). Currently, all conventional CVD processes have failed to make useful ε<2.7, Ta-compatible thin films. Due to many unique advantages that will be revealed in the following sections, we believe that TP soon will emerge as a primary CVD approach for fabrications of future IC's.

Conventional CVD Processes:

There are several fundamental differences between the TP and conventional CVD processes. First, in all traditional CVD processes, starting chemicals are introduced into a CVD chamber where the “feed chemicals” are subjected to needed energy sources such as plasma or ozone to generate reacting intermediates. Film will grow when these intermediates impinge onto a substrate such as a wafer. Second, in these CVD processes, wafer is normally heated and a CVD chamber is normally operated under sub-atmosphere pressure or moderate vacuum in the ranges of few mTorrs to few Torrs. Third, in these CVD processes, film not only grows on wafer but also on chamber wall. Fourth, conventional CVD processes using ozone oxidative processes are not suitable for making organic thin films. Current CVD dielectrics that are prepared from plasma polymerization of Organo-Siloxanes have ε of about 2.7 or higher.

Plasma polymerization of organic precursors can provide ε of lower than 2.7, however, they inherit many drawbacks, these include:

1. Due to poorly selective cracking of chemical bonds by plasma, some feed chemicals can end up with several reactive sites but others still have none during plasma polymerization. To avoid this disparity by increasing power levels for instance, films with highly cross-linked density and high residual stress would result.

2. During plasma polymerization, free radicals, anions, and ions with various reactive sites on each intermediate will be generated. Since intermediates with different molecular orbital configurations likely will not react with each other, some of these intermediates will have no chance to react and become a part of the resulting network. Due to this inherent complexity, plasma polymerization commonly results in poor yield (few percent) and films with different chemical structures at molecular levels.

3. Since all kinds of reactive intermediates, including very corrosive fluorine ion or radical could be generated, it is also desirable to heat the substrate, so condensation of low molecular weight products, corrosive species and not reacted impurities can be avoided. However, with presence of corrosive species such as fluorine ion, corrosion of underlying metal such as a barrier metal on wafer can become a serious problem when wafer is kept at high temperatures.

4. In addition, when more than 15 to 20 molar % of multi-functional intermediates consisting of more than two reactive sites are present inside chamber, most of these reactive sites will be trapped inside the polymer networks or become chain ends. Post annealing is done under controlled reductive or hydrogen atmosphere before the film is removed from vacuum chamber. This is needed to eliminate these reactive chain ends in order to avoid later reactions of these reactive chain ends with undesirable chemicals such as water or oxygen.

5. Finally, presence of many polymer chain-ends and pending short chains in polymer networks will result in high dielectric loss, thus the resulting dielectric will not be useful for high frequency (GHz) applications that are critical to most future IC applications.

The State of Transport Polymerization:

Transport polymerization (“TP”) employs known chemical processes to generate desirable reactive intermediates among other chemical species. Chemical processes that are particularly useful for this invention include photolysis and thermolysis. These two chemical processes can generate useful reactive intermediates such as carbenes, benzynes and other types of diradicals using appropriate precursors.

Transport polymerization (“TP”) of poly (Para-Xylylenes) (“PPX”) for the coating of circuit boards and other electronic components has been used since the early 1970s. Currently, all commercial PPX dielectric films are prepared by the Gorham method (Gorham et al., U.S. Pat. No. 3,342,754, 1967). The Gorham method employed dimer precursor (I) that cracks under high temperatures (e.g. 600 to 680° C.) to generate a reactive gaseous diradical (II) under vacuum. When adsorbed onto cold solid surfaces, the diradical (II) polymerizes to form a polymer film.

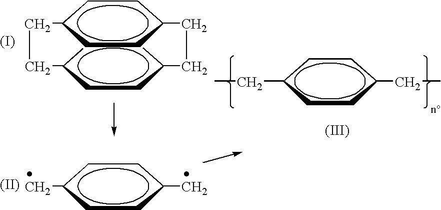

A commercially available polymer film that is similar to equation (III) (e.g. {—CX₂—(C₆H₄₋ₙZₙ-CX₂—}, X=H and Z=Cl), resulted in a film with a dielectric constant, ε ranging from 2.5 to 3.2. However, the resultant films were not thermally stable at temperatures higher than 300 to 350° C., and were not useful for fabrications of future IC's that require dielectric with lower ε and better thermal stability. Although not wanting to be bound by theory, the PPX films can be prepared by polymerization of their corresponding reactive diradical intermediates via transport polymerization. (Lee, J., Macromol, et al., Sci-Rev. Macromol. Chem., C16(1) (1977-78)). Examples of other PPX films and their repeat units resulting from polymerization of the diradical intermediates include commercially available products, such as: PPX-N (—CH₂—C₆H₄—CH₂—); perfluoro PPX (—CF₂—C₆F₄—CF₂—); and PPX-F (—CF₂—C₆H₄—CF₂—). PPX-F has a ε=2.23. It is thermally stable up to 450° C. over 2.5 hours in vacuum. Therefore, rigorous attempts have been made to make PPX-F from dimer (—CF₂—C₆H₄—CF₂—) (Wary et al., Proceedings, 2nd Intl. DUMIC, 1996 pp207-213; ibid, Semiconductor Int'l, 19(6), 1996, p211-216) using commercially available equipment. However, these efforts were abandoned due to high cost of the dimer and incompatibility of the barrier metal (e.g. Ta) with PPX-F films prepared by TP (Lu et al., J. Mater. Res., Vol., 14(1), p246-250, 1999; Plano et al., MRS Symp. Proc., Vol. 476, p213-218, 1998—these cited articles are herby incorporated by reference.

Many commercial process modules have been available for deposition of PPX since early 1970, and comprise of primarily the same four main components, as shown in the FIG. 1. For example, a sample holder and material delivery system 100 is in fluid communication with a thermal reactor 120 through a needle valve 110. The deposition chamber 130 is in fluid communication with the reactor 120 and the cold trap 140. Additionally the entire system is connected to a vacuum system connected to the cold trap 140.

In these process modules, a resistive heater and a stainless steel reactor (i.e. pyrolyzer) are used to crack dimers. Additionally, a tubular quartz reactor has demonstrated the ability in a laboratory system to crack a dimer (e.g. {—CH₂—C₆H4—CH₂—}₂ as shown above in equation (I)), and used for making PPX-N (Wunderlich and associates (Wunderlich et al., Jour. Polymer. Sci. Polymer. Phys. Ed., Vol. 11, (1973), pp 2403-2411; ibid, Vol. 13, (1975), pp1925-1938). Although not wanting to be bound by theory, it is important to note that a PPX—N dimer (e.g. {—CH₂—C₆H4—CH₂—}₂) bears no halogen, and thus there was no potential corrosion of the stainless steel reactor during preparation of PPX-N. In other word, a stainless steel pyrolyzer can only be used for a dimer that has halogens on a Sp²C carbon to make PPX-C & D, but it is not compatible with a precursor consisting of halogens on the Sp³C. For example, when a precursor, such as:

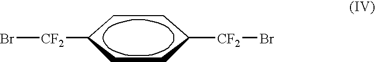

is used, the iron inside the pyrolyzer's surfaces can react with the bromine if the temperature inside the pyrolyzer is higher than 450 to 500° C. The resulting iron bromide would contaminate the dielectric film and make it unsuitable for IC fabrications. Other shortcomings of commercial PM's are that they are not equipped with a proper deposition chamber for wafer or a vapor flow controller (“VFC”), which are critical to the current invention. Thus, these commercial process modules are not useful for the present invention that uses halogen-containing precursors.

The U.S. Pat. No. 5,268,202 with Moore listed as inventor (“the Moore '202 patent”), teaches that a dibromo-monomer (e.g. IV={Br—CF₂—C₆Cl₄—CF₂—Br}) and a metallic “catalyst” (Cu or Zn) inside a stainless steel pyrolyzer can be used to generate reactive free radical (V) according to the reaction (3). However, to lower the cost of starting materials, a large proportion (>85 to 95 molar %) of a more readily available co-monomer with structure {CF₃—C₆H₄—CF₃} could be used to make PPX-F.

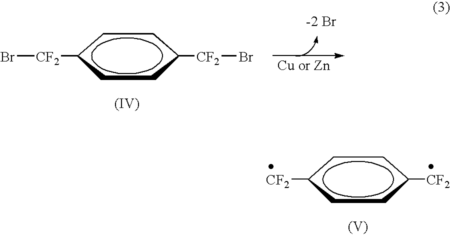

There are several key points that need to be addressed concerning the usage of the monomer (IV) in reaction (3). First, an earlier U.S. Pat. No. 3,268,599 (“the Chow '599 patent”) with Chow listed as inventor, revealed the chemistry to prepare a dimmer as early as 1966. However, the Chow '599 patent only taught the method to prepared dimer {CF₂—C₆H₄—CF₂}₂ by trapping the diradical (V) in a solvent. Furthermore, the equipment and processing methods of the Chow '599 patent employed were not suitable for making thin films that are useful for IC fabrications using a Cu-dual damascene process. Second, according to the Moore '202 patent, the above reaction (3) would need a cracking temperature ranging from 660-680° C., without using the “catalysts.” However, we found that metallic “catalysts” such as Zn or Cu would readily react with organic bromine at temperatures ranging from 300 to 450° C., the pyrolyzer temperatures employed by the Moore '202 patent. Formation of metallic halides on surfaces of these “catalysts” would quickly deactivate these “catalysts” and inhibit further de-bromination shown in reaction (3). In addition, the presence of Zn and Cu halides inside a pyrolyzer would likely cause contamination for the process module and dielectric films on wafer. Third, cooling of reactive intermediate and wafer cooling could not be efficient because both the wafer holder and pyrolyzer were located inside a close system for the deposition chamber that was used in the Moore '202 patent. Consequently, the process module used by the Moore '202 patent cannot be useful for preparation of thin films of this invention.

An earlier U.S. Pat. No. 6,140,456 with Foggiato et al., listed as inventors (“the Foggiato '456 patent”) claimed new starting materials and chemical processes that are used to make fluorinated poly(para-xylylenes) (“F-PPX”) and fluorinated poly(para-fluoroxylylenes) (“F-PPFX”). The processes reveled in the Foggiato '456 patent utilize low cost starting materials, catalysts, chemical reactors, transport polymerization (“TP”) systems, and chemical vapor deposition (“CVD”) systems commonly used for making F-PPX. Additionally, new TP and CVD deposition systems were also used to make F-PPX and F-PPFX. The Foggiato '456 patent claimed that the polymers were used for the manufacture of low dielectric films with high thermal stability and are sufficiently strong to withstand planarization and polishing for the manufacture of integrated circuits. Additionally the Foggiato '456 patent claimed processes to generate intermediates including a dialdhyde precursor and a fluorinating agent and a TP CVD process to generate reactive intermediate for polymerization. Although not wanting to be bound by theory, it is impractical to build a reactor, or a series of reactors for the processes revealed in the Foggiato '456 patent for use in industrial semiconductor applications. In particular, it is undesirable to use a pressurized reactor to make tetrafluoro-precursors as claimed by the Foggiato '456 patent.

The Foggiato '456 patent describes a photon assisted transport polymerization (“PATP”) of poly(para-xylylenes) using ultraviolet (“UV”), vacuum ultraviolet (“VUV”), and/or infrared (“IR”) sources, which is illustrated in FIG. 3 of the Foggiato '456 patent. The photolytic reactor from the Foggiato '456 patent was not useful for the present invention. For example, when 3 square centimeters (“sccm”) of dibromo-precursor (IV) was passed through a Quartz Reactor under a Mercury Halide lamp (ν=220 to 350 nm@120 mWatt/cm²) for 10 minutes, film deposited was not observed to form on a wafer substrate. Similar result was observed, when a pulsed UV that generated much powerful and stronger UV (ν≦200 to 220 nm with pulse of over 1000 mWatt/cm²; from Xenon's lamp for excimer UV) was used. Whereas under similar vacuum conditions (e.g. a few mTorrs), and at a wafer temperature of −30° C., deposition of a film could be detected if a different type of deposition system was utilized.

The current invention avoids several problems that are encountered by both the CVD process, and TP process. The current invention describes a transport polymeraization reactor (“TP reactor”) equipped with a UV energy source designed to crack specific precursor materials that are described for this invention. The TP reactor equipped with the UV energy source avoids several problems of prior art by cracking the precursor in one chamber and then transporting the intermediate molecules into a different deposition chamber. By utilizing a UV-reactor of this invention, the reactor needs no cleaning for the coke formation as the conventional thermal reactor that used for commercial transport polymerization. Further, the resultant intermediates can be easily separated using the fractionation device from other photolytic products, thus the resultant film will have higher purity and better properties. Moreover, the concentration of the transported intermediates may be kept low using VFC, to discourage re-dimerization of intermediates. Thus, the thin films of low dielectric material have higher purity and have better physical, mechanical and electrical properties than film deposited by conventional CVD and TP that uses a thermal reactor. These films resulted form this invention thus have higher mechanical strength and better electrical properties and are more reproducible manufacturing of integrated circuits.

### SUMMARY

Therefore, one object of this invention is provide useful precursors and chemical processes that are useful for making low k dielectric thin films that are useful for fabrications of future IC's. Another object of this invention is to provide a Photo-Reactor that can provide controllable amounts of high purity intermediates that are useful for making low k dielectric thin films that are useful for fabrications of future IC's. Another object of this invention is to provide an UV reactor that requires no post-deposition cleaning and increase throughput and lower the cost of operation.

One aspect of this invention is the design of a UV reactor. A vacuum vessel fabricated from a UV transparent material is essential for this invention. In a specific embodiment of the present invention, high purity or single crystal quartz is used as a vacuum vessel fabrication material. The vacuum vessel should have a level control and a temperature control. An inlet provides a means for precursors to enter the vacuum vessel. Additionally the outlet provides a means for intermediates to exit the vacuum vessel. The UV energy source provides photon energy for photodissociation reactions. Another component of the UV reactor is a fractionation column having a temperature control fluid. The heated fractionation column is in fluid communication with the outlet of the vacuum vessel, and a vapor flow controller (“VFC”) valve. The VFC is used to regulate the feed rate of reactive intermediates into a deposition system.

Alternatively, the VFC could be utilized to regulate the feed rate of precursors into the vacuum vessel. However, such an arrangement would also require the addition of a heated container for precursor material. The heated precursor container would provide enough vapor-precursors to be regulated by the VFC. The alternative UV reactor would comprise a vacuum vessel fabricated from a UV transparent material (e.g. high purity or single crystal quartz). The vacuum vessel should have a level control, a temperature control, and an inlet to provide a means for precursors to enter the vacuum vessel from the VFC. Additionally the outlet provides a means for intermediates to exit the vacuum vessel. Another component of the UV reactor is a fractionation column having a temperature control fluid. The UV energy source provides photon energy for photodissociation reactions. However, an optional thermal reactor can be placed after the fractionation column to assure full dissociation of the precursors into reactive intermediate precursors before entering the deposition system.

The present invention is directed to a UV transport polymerization (“TP”) reactor useful for making a thin film from precursors to be utilized in the fabrication of integrated circuits. More specifically, this invention describes an UV reactor that utilizes an UV energy source to photodissociate specific leaving groups in precursors to form reactive intermediates. The reactive intermediates that pass into a deposition chamber to form a thin film useful for the fabrication of integrated circuits.

The UV reactor has several components. For example, a first aspect of the present invention relates to a vacuum vessel fabricated from a UV transparent material. The vacuum vessel also contains a level control and a temperature control. Additionally, an inlet in the vacuum vessel is in fluid communication a heated fractionation column that having a temperature control fluid in fluid communication with an outlet; a vapor flow controller (“VFC”) valve in fluid communication with the fractionation column and deposition chamber.

### BRIEF DESCRIPTION OF THE DRAWINGS

FIG. 1 shows the four main components of a conventional deposition system for transport polymerization;

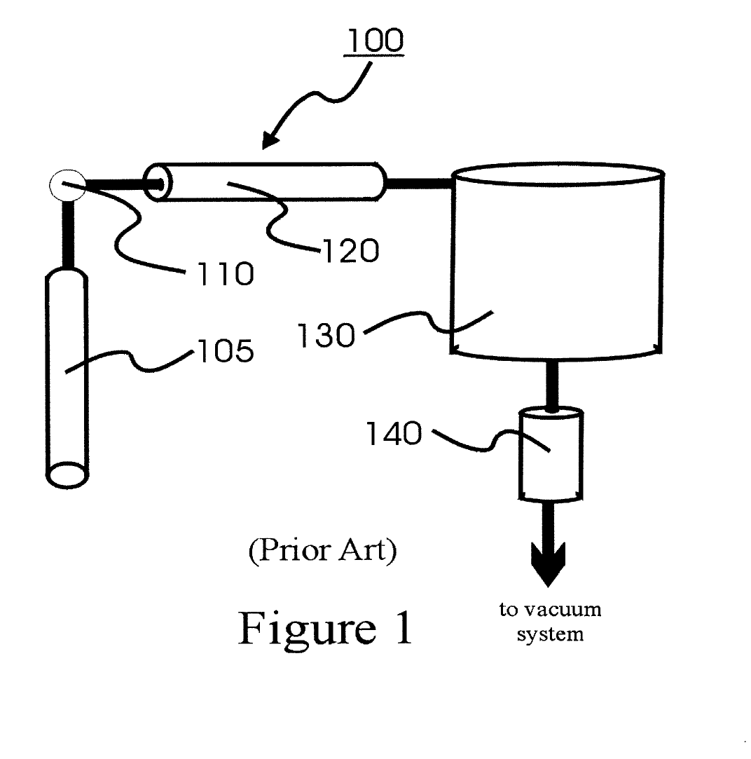

FIG. 2 shows a design for an apparatus comprising a UV transparent vessel, a UV radiation source, a fractionation column, and a vapor flow controller (“VFC”) valve that are used together to deliver intermediates to a deposition chamber;

FIG. 3 shows an alternative design for an apparatus comprising a vapor flow controller (“VFC”) valve, a UV transparent vessel, a UV radiation source, and a fractionation column that are used together to deliver intermediates to a deposition chamber.

### DETAILED DESCRIPTION OF PREFERRED EMBODIMENTS

For the past 20 years, the integrated circuits (IC) density has doubled about every 18 months. The present lack of preparation methods for making qualified low dielectric materials now threatens to derail the continued shrinkage of future IC's. This invention discloses a UV reactor useful for making thin films from precursors to be utilized in the fabrication of integrated circuits. More specifically, this invention describes a UV reactor that comprises a reactor device that facilitates the efficient cracking of precursor materials utilizing UV energy. The UV energy is useful for breaking the chemical bonds of a desired leaving groups in the precursor, but does not break the chemical bonds of other leaving groups in the precursor molecule. The various materials that can be used to fabricate the UV reactor are also revealed. In order for a UV reactor to be useful for this invention, it must generate useful reactive intermediates with high efficiency and have low side reaction products. With this in mind, there are several unique advantages for using electromagnetic radiation (e.g. infrared (“IR”) and UV) if the IR or UV reactor is designed properly. For example, since UV under a vacuum produces no heat, the designs for a process module (“PM”) would have less constrains. For example, high temperatures in prior art TP reactors leads to “coke” formation and PM's must incorporate cleaning subsystems for removal of the carbon formed inside a thermal reactor. Such cleaning subsystems not only increase the design complexity for a given PM deposition system, but the increased complexity reduces throughput for film deposition. Consequently, a photolytic process for removing specific leaving group would be very selective at low temperatures, and “coke” formation could be avoided entirely. Thus, the UV reactor can overcome several problems associated with prior art. Other objects, aspects and advantages of the invention can be ascertained from the review of the detailed disclosure, of the examples, the figures and the claims.

Precursors for the Photolytic Process: Instead of using a conventional tubular stainless steel pyrolyzer, the preferred embodiment of the present invention requires a specially designed UV Reactor that facilitates new precursor chemistries and deposition processes used to prepare low ε thin films. Although not wanting to be bound by theory, the UV reactor needs to generate useful reactive intermediates with high efficiency and low side-reaction product from precursors that have a general chemical structure as shown in formula (VI).

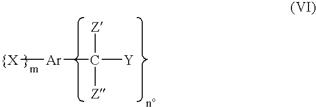

wherein, n^{o} or m are individually zero or an integer, and (n^{o}+m) comprises an integer of at least 2 but no more than a total number of sp²C—X substitution on the aromatic-group-moiety (“Ar”). Ar is an aromatic or a fluorinated-aromatic group moiety. Z′ and Z″ are similar or different, and individually a hydrogen, a fluorine, an alkyl group, a fluorinated alkyl group, a phenyl group or a fluorinated phenyl group. X is a leaving group, and individually a —COOH, —I, —NR₂, —N⁺R₃, —SR, —SO₂R, wherein R is an alkyl, a fluorinated alkyl, aromatic or fluorinated aromatic group, and Y is a leaving group, and individually a —Cl, —Br, —I, —NR₂, —N⁺R₃, —SR, —SO₂R, or —OR, wherein R is an alkyl, a fluorinated alkyl, aromatic or fluorinated aromatic group. Furthermore, the aromatic is preferably a fluorinated aromatic moiety including, but not limiting to, the phenyl moiety, —C₆H₄₋ₙFₙ (n=0 to 4) such as —C₆H₄— and —C₆F₄—; the naphthenyl moiety, —C₁₀H₆₋ₙFₙ— (n=0 to 6) such as —C₁₀H₆— and —C₁₀F₆—; the di-phenyl moiety, —C₁₂H₈₋ₙFₙ— (n=0 to 8) such as —C₆H₂F₂—C₆H₂F₂— and —C₆F₄—C₆H₄—; the anthracenyl moiety, —C₁₂H₈-nFₙ; the phenanthrenyl moiety, —C₁₄H₈₋ₙF₂—; the pyrenyl moiety, —C₁₆H₈₋ₙFₙ— and more complex combinations of the phenyl and naphthenyl moieties, —C₁₆H₁₀₋ₙFₙ—. Note that isomers of various fluorine substitutions on the aromatic moieties are also included in this invention.

The functional requirements for the UV Reactor are largely determined by chemical structure of leaving groups X and Y and chemical methods that used to remove them in reactor. The leaving groups can be removed from precursors of formula (VI) by several different chemical methods. The methods that generate reactive intermediates under vacuum or under inert atmosphere include, but are not limited to:

irradiation using photons or electrons

cracking using thermal heat,

plasma energy, or

microwave energy

Although not wanting to be bound by theory, in order for a UV reactor to be useful for this invention, it must generate useful reactive intermediates with high efficiency and have low side reaction products. With this in mind, there are several unique advantages for using electromagnetic radiation (e.g. IR and UV) if the IR or UV reactor is designed properly. For example, since UV under a vacuum produces no heat, designs for a process module (“PM”) would have less constrains. In addition, a photolytic process for removing specific leaving group would be very selective at low temperatures, and “coke” formation would be as found in thermal reactors could be avoided. Cleaning for carbon formed inside a thermal reactor will not only increase the design complexity for a deposition system but also reduce throughput for film deposition.

Functional requirements for the UV Reactor are largely determined by chemical structure of leaving groups (“LG”) and chemical method that used to remove the LG in reactor. For instances, when the leaving group is —Br, I, Cl, —OR, —NH or —SR group, the required photolytic energy source should be respectively higher than 2.52, 3.52, 3.09 and 3.20 eV (A. Streitweissser et al “Introduction to Organic Chemistry”, Appendix II. UC Berkeley Press (1992)). However, choosing a proper energy source is only a necessary step but not sufficient conditions for making thin films that are useful for fabrications of future IC's. In addition, a properly designed UV Reactor is needed.

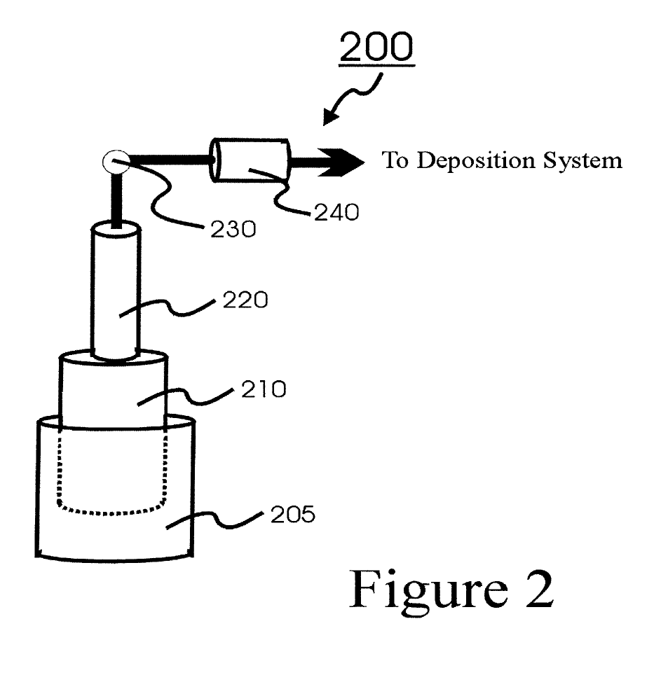

UV Reactor of this invention: A useful photolytic reactor should provide sufficient amounts of high purity reactive intermediates for fabrications of future IC's. A useful Photo Reactor consists of at least two functional components as shown in FIG. 2. The apparatus shown in 200 illustrates an apparatus that provides reactive intermediates for transport polymerization. Precursors flow into the UV reactor vessel 210. A photon source 205 is a device that generates UV photons, wherein the photon source comprises a Mercury Vapor Lamp or a Metal Halide Lamp that is available commercially (e.g. Eamcast Inc). The UV lamps provide UV intensities from 50 to 250 mWatts/cm² and photon energies range from 2 to 5 eV, which are useful for this invention. These UV lamps are relatively inexpensive, thus are useful for this invention. When UV lamps are used, the UV reactor vessel 210 should be constructed from a UV transparent material. Quartz, especially high purity or single crystal quartz that has high transparency to UV in the 200 to 350 nM range, and is one aspect of the current invention.

Alternatively, vacuum UV or incoherent excimer radiation that is generated from dielectric barrier discharge with a photon wavelength in the range of 150 to 220 nm is also useful for this invention. For example, ArF generates 193 nm, Xe generates 172 nm, or Kr generates 222 nm UV is particularly useful for photolysis of C—Br bonds in the above precursors (V). When the vacuum UV is used, the LV reactor vessel 210 should be constructed from high purity MgF₂, CaF₂ or LiF that is high transparency to LV in the ranges of 150 to 200 nm. Other materials can be utilized providing that the short wavelengths of vacuum UV can pass easily.

The residence time for vapor precursors in a vacuum reactor can range from few mini-seconds to less than few seconds. Due to short residence time, none of the above UV sources are expected to provide film growth of few thousands Å/min on a 300 mm wafer. To overcome this limitation, the present invention a uses liquid precursor source in the container 210 that is connected to a fractionation column 220. The fractionation column is then connected to a vapor phase controller 230 that is used to regulate the feed rate of the chemicals to the deposition chamber. Due to presence of high concentration of precursors in the container, UV irradiation will generate sufficient amounts of intermediates over time of deposition. Due to selective photolysis reaction, only useful intermediates and the leaving group will be generated inside the UV reactor vessel 210. It is important to notice that the vapor pressure of the leaving group and intermediates is higher than the precursors due to lower mass. Under this case, the fractionation column 220 serves exactly an identical purpose that chemists use for vacuum distillation. For example, under vacuum condition, by choosing proper temperature and “plate number” of the fractionation column, the leaving group and intermediates will be distilled preferentially and removed from the container, whereas the precursors will be left for further exposure to UV irradiation. The technology to build a useful fractionation column and finding the conditions to run the fractionation have been practiced daily by chemists and those skillful in the art, thus are not to be further explained here.

The above UV Reactor 200 is particularly useful for transport polymerization (“TP”) using a precursor that consists of a halide as leaving group. For example in chemical structure (VI), m=0, n=2, Y=Cl, Br or I. It has been reported that de-bromination of Br—CF₂—CF₂—Br (“Halon 2402”) compound can be facilitated by Vacuum UV at 193 nm, or UV at 233 and 266 nm wavelength and the quantum yield (“Φ(Br, Br*)”) is 2 and 1.4 respectively. (Peng Zou et al. “Quantum Yields and Energy Partitioning in the UV photodissociation of Halon 2402),” Jour. of Chem. Phys., Vol 113, No.17, P 7149 (2000)). This means photo dissociation of both bromine can occur with a single UV photon adsorption at the 193 and 233 nm. Although not wanting to be bound by theory, the mechanism for the photodissociation of the Halon 2404 actually involves two steps:

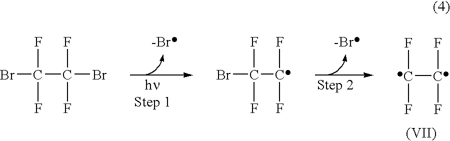

During step 1, Bromine is liberated from the base molecule with a photon of energy. Depending on wavelength of the UV, reactions may have high translational energy. If high translational energy is present, the monobromine intermediate may undergo a secondary dissociation (“step 2”) without needing additional photon of energy. Thus, a desired intermediate of formula (VII) results. When specific precursors are used, such as compound (VI), (wherein, m=0, n=2, Y=Br), the secondary photo dissociation may not occur immediately following the primary photo dissociation of reaction. For example, the chemical equation (5) illustrates a situation wherein the reactive intermediate (VIII) results:

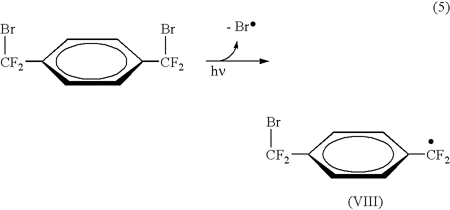

Under this situation, bi-molecular collision may occur such that two monobromine intermediates (VIII) react together and form undesirable high molecular weight product (IX). However, in order for this to occur the concentration of the intermediate (VIII) must be at high concentrations:

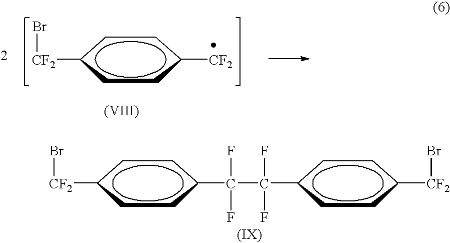

Therefore, it is very important to select proper distillation conditions so that the concentration of the primary intermediates (e.g. VIII) found inside the container 210 shall not reach a point that bimolecular collisions of intermediates become possible and form undesirable products (e.g. IX). The resulting di-bromine compound, (IX) has too high molecular weight upon further debromination, thus is not easy to be transported to deposition chamber for film growth.

Further dissociation of the mono-bromine intermediate (VIII) may occur during or after its distillation from the container of the precursor, or by using another thermal reactor following the UV reactor. In the later case, the thermal reactor needs to be operated only at temperatures ranging from 150 to 350° C., which is far below the carbon formation temperatures of 400 to 450° C. A chemical equations of this process is shown in equation 7:

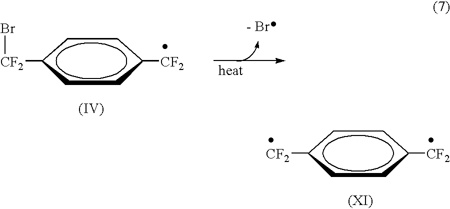

Under such circumstances, a monobromine intermediate (VIII) can go under a secondary de-bromination without further adsorption of photon. The resulting diradical should have a composition as shown in (XI). However, it is desirable to keep the concentration of (XI) low to avoid bi-molecular collision of the diradical (XI). Under the concentration that dimerization can occur, cyclic dimer as well as polymers will form in the container 210, thus reducing the yield of the polymer film that can grow inside the deposition chamber. The formation of dimer and polymer under this condition can be seen from solid precipitation of these undesirable products in a transparent container. When this happens, the “plate number” of the fractionation column should be increased, or, and the distillation temperature or the vacuum should be increased to remove more intermediates quickly. Alternatively, the photon density from the UV sources can be lowered to lower the conversion rate for photolysis. However, one should always try to use sufficient UV photon density to provide high growth rate of polymer film in the deposition chamber.

Although not wanting to be bound by theory, one of the ways to avoid dimerization of monobromine (VIII), or/and dimerization and polymerization of diradical (XI) is to use a non-reactive chemical (“NRC”) to dilute the precursor and other reaction intermediates (e.g. VIII or/and XI). The suitable concentration of precursor should be in range from about 1 to 30%, preferably from about 3 to 10%, depending on the efficiency of fractionation condition employed. An ideal NRC that is useful for this application should be chemically compatible with the precursor, so precursor can be homogeneously dispersed or dissolved in it. Although not wanting to be bound by theory, the NRC should have much higher boiling points and practically no vapor pressure under the photo-chemical conditions used for the reaction as shown in equations 5 and 7. For example, a polybromine compound such as pentabromo-biphenylether, and polyaromatic compounds having more than 12 carbons, preferably 20 to 24 carbons are useful as NRC. Other UV resistant polymers are also useful for this application. For example, fluid or linear polysiloxanes, in particular vacuum grade polysiloxanes that consists of very little low molecular weight siloxanes, are also useful for this application.

The UV Reactor 200 is in fluid communication with a Vapor Flow Controller (“VFC”) 230, which is used to regulate the amounts of the intermediates that enter the deposition chamber. It has also been contemplated by the inventors that the UV reactor can be used in conjunction with the thermal reactor. If the UV reactor and the thermal reactor are to be used, the VFC should preferably be interposing the two reactors. Although not wanting to be bound by theory, it is preferred that the VFC is heated under vacuum to prevent the condensation of intermediates inside the VFC. Thus, the temperature should be above the condensation or ceiling temperature of the intermediates (e.g. VIII and XI).

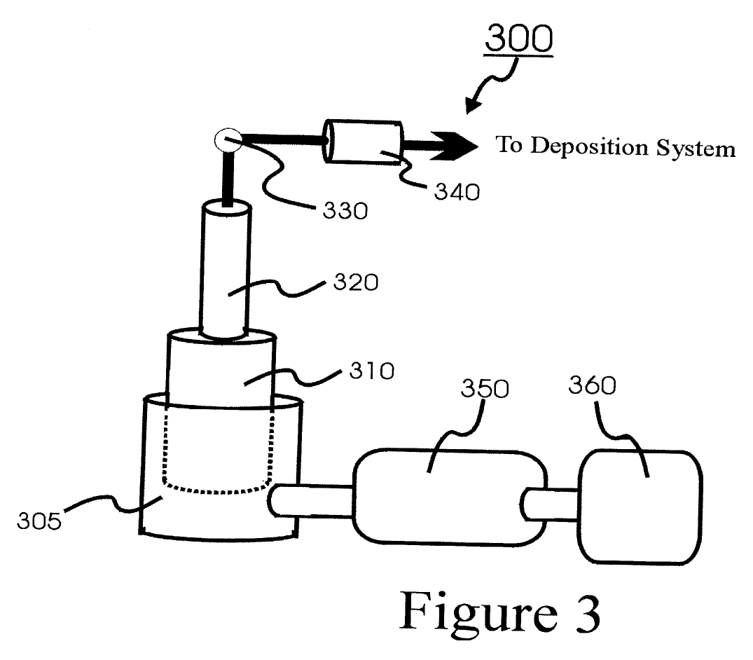

FIG. 3 shows an alternative aspect for the UV Reactor. The VFC 350 is in fluid communication and placed in front of the UV Reactor 310, which is filled with NRC to prevent reaction of reactive intermediates (e.g. VIII or XI) inside the UV Reactor 310. The apparatus shown in the FIG. 3 allows heated precursors from a heated precursor container 360 to flow through a tube and provide sufficient vapor precursors for the VFC to regulate the flow of small amounts of heated precursors into the Reactor 310. In order to prevent dimerization or polymerization of the reactive intermediates (e.g. VIII or XI) inside the UV reactor 310, the concentration of precursor at any given time should be kept below a few percent in the NRC. The fractionation column 320 in FIG. 3 is used to separate the reactive intermediates (e.g. VIII or XI) from the un-reacted precursor inside the UV reactor 310, which is similar to the function of the fractionation column 220 in FIG. 2. However, if the reaction products consist of a mono-radical intermediate (e.g. VIII), an option is provided for these reaction products to be sent through the thermal reactor 340. In addition, if the reaction products from the fractionation column 320 consist of only of a diradical intermediate (e.g. XI), then the reaction products can be directly introduced to the deposition chamber the trap can be used at the exit of the thermal reactor. Alternatively, the UV reactor 310 or the fractionation column 320 can be connected to a trap 330, which is utilized for trapping the undesirable leaving groups or undesirable photolytic side products from the gas products generated inside the reactor. The trap 230 then is connected to the VFC 240 as shown in the FIG. 2, or to the thermal reactor 340 then to the deposition chamber as shown in FIG. 3. Alternatively, when an additional thermal reactor is used in conjunction with the UV reactor,

It should be appreciated by those of ordinary skill in the art that other embodiments may incorporate the concepts, methods, precursors, polymers, films, and devices of the above description and examples. The description and examples contained herein are not intended to limit the scope of the invention, but are included for illustration purposes only. It is to be understood that other embodiments of the invention can be developed and fall within the spirit and scope of the invention and claims. For example, all of the above discussions assume a single UV Reactor per one deposition chamber; however, those who are skillful in tool designs can easily apply the above principles to make a larger UV Reactor for industrial cluster tools that have multi-deposition chambers.

What is claimed is:

1. An ultra violet (“UV”) reactor subsystem useful for making a thin film from a precursor comprising:
(a) a vacuum vessel fabricated from an UV transparent material having a liquid level control and a temperature control;
(b) an inlet in fluid communication with the vacuum vessel;
(c) a fractionation column having a temperature control fluid in fluid communication with an outlet;
(d) a vapor flow controller (“VFC”) valve in fluid communication with the fractionation column; and
(e) an UV energy source in a spaced relationship with the vacuum vessel.

2. The UV reactor subsystem of claim 1, wherein a diluted-precursor entering from the inlet absorbs a photon from the UV energy source and is photodissociated in the vacuum vessel forming a reactive intermediate that passes into the fractionation column through the outlet and through the VFC into a deposition chamber.

3. The UV reactor subsystem of claim 2, wherein the diluted-precursor is diluted in a non-reacting chemical (“NRC”).

4. The UV reactor subsystem of claim 2, wherein the UV source provides a wavelength of UV radiation in the range of ranging from about 150 to 350 nm.

5. The UV reactor subsystem of claim 2, wherein the UV source provides a wavelength of UV radiation in the range of ranging from about 190 to 270 nm.

6. The UV reactor subsystem of claim 2, wherein the UV source provides a UV photon intensity in the range of about 20 mWatts/cm² to about 10 Watts/cm².

7. The UV reactor subsystem of claim 2, wherein the UV photon is UV energy source comprises a mercury vapor lamp.

8. The UV reactor subsystem of claim 2, wherein the UV source comprises incoherent excimer radiation derived from a dielectric gas discharge.

9. The UV reactor subsystem of claim 8, wherein the dielectric gas is selected from a group consisting of: Xe₂, Kr₂, XeCl, ArF, ArCl, KrF, KrCl and KrBr.

10. The UV reactor subsystem of claim 1, wherein the UV transparent material is quartz.

11. The UV reactor subsystem of claim 1, wherein the UV energy source comprises a Metal Halide Lamp.

12. The UV reactor subsystem of claim 1, wherein the precursor has a general chemical structure: 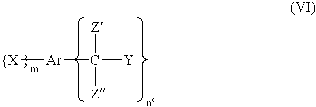
wherein: n^{o} or m is individually zero or an integer, and (n^{o}+m) comprises an integer of at least 2 but no more than a total number of sp²C—X substitution on the aromatic-group-moiety (“Ar”),
Ar is an aromatic or a fluorinated-aromatic group moiety,
Z′ and Z″ are similar or different, and individually a hydrogen, a fluorine, an alkyl group, a fluorinated alkyl group, a phenyl group or a fluorinated phenyl group;
X is a leaving group, and individually a —COOH, —I, —NR₂, —N⁺R₃, —SR, —SO₂R, wherein R is an alkyl, a fluorinated alkyl, aromatic or fluorinated aromatic group, and
Y is a leaving group, and individually a —Cl, —Br, —I, —NR₂, —N⁺R₃, —SR, —SO₂R, or —OR, wherein R is an alkyl, a fluorinated alkyl, aromatic or fluorinated aromatic group

13. The ultra violet (“UV”) reactor subsystem of claim 12, wherein a bonding energy between the leaving group (“(BE)_{L}”) and a core group of the precursor is less than 75 Kcal/Mole, and the range of the (BE)_{L} is about 20 to 45 Kcal/Mole lower than a bonding energy of a next weakest chemical bond energy (“(BE)_{c}”) present in the precursor.

14. The UV reactor subsystem of claim 12, wherein the leaving group is a halide.

15. The UV reactor subsystem of claim 14, wherein the halide is Br.

16. The UV reactor subsystem of claim 14, wherein the halide is I.

17. The UV reactor subsystem of claim 14, wherein the halide is Cl.

18. The UV reactor subsystem of claim 1, wherein the VFC delivers about 0.1 to 1000 square centimeters (“sccm”) of precursor to a deposition system.

19. The UV reactor subsystem of claim 1, wherein the VFC delivers about 2 to 10 square centimeters (“sccm”) of precursor to a deposition system.

20. An ultra violet (“UV”) reactor subsystem useful for making a thin film from a precursor comprising:
(a) a heated precursor vessel in fluid communication with a vapor flow controller (“VFC”) valve;
(b) a vacuum vessel fabricated from an ultraviolet (“UW”) transparent material having a level control, and a temperature control;
(c) an inlet on the vacuum vessel in fluid communication with the VFC;
(d) a fractionation column having a temperature control fluid in fluid communication with an outlet on the vacuum vessel; and
(e) an ultra violet (“UV”) energy source in a spaced relationship with the vacuum vessel.

21. The UV reactor subsystem of claim 20, wherein the heated precursor container provides a vapor-precursor that allows the VFC to regulate small amounts of the vapor-precursor entering the inlet as a diluted precursor; wherein the diluted-precursor absorbs a photon from the UV energy source and is photodissociated in the vacuum vessel forming a reactive intermediate that passes into the fractionation column through the outlet and through the VFC into a deposition chamber.

22. The UV reactor subsystem of claim 21, further comprising a thermal reactor positioned between the fractionation column and the deposition chamber; and in fluid communication with the fractionation column and the deposition chamber.

23. The UV reactor subsystem of claim 21, wherein the diluted-precursor is diluted in a non-reacting chemical (“NRC”).

24. The UV reactor subsystem of claim 21, wherein the UV source provides a wavelength of UV radiation in the range of ranging from about 150 to 350 nm.

25. The UV reactor subsystem of claim 21, wherein the UV source provides a wavelength of UV radiation in the range of ranging from about 190 to 270 nm.

26. The UV reactor subsystem of claim 21, wherein the UV source provides a UV photon intensity in the range of about 20 mWatts/cm² to about 10 Watts/cm².

27. The UV reactor subsystem of claim 21, wherein the UV photon intensity comprises a discharge from Mercury vapor.

28. The UV reactor subsystem of claim 21, wherein the UV source comprises incoherent excimer radiation derived from a dielectric gas discharge.

29. The UV reactor subsystem of claim 28, wherein the dielectric gas is selected from a group consisting of: Xe₂, Kr₂, XeCl, ArF, ArCl, KrF, KrCl and KrBr.

30. The UV reactor subsystem of claim 20, wherein the UV transparent material is quartz.

31. The UV reactor subsystem of claim 20, wherein the UV energy source comprises a metal halide lamp.

32. The UV reactor subsystem of claim 20, wherein the precursor has a general chemical structure: 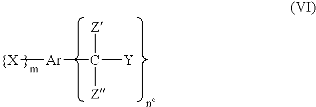
wherein: n^{o} or m is individually zero or an integer, and (n^{o}+m) comprises an integer of at least 2 but no more than a total number of sp²C—X substitution on the aromatic-group-moiety (“Ar”),
Ar is an aromatic or a fluorinated-aromatic group moiety,
Z′ and Z″ are similar or different, and individually a hydrogen, a fluorine, an alkyl group, a fluorinated alkyl group, a phenyl group or a fluorinated phenyl group;
X is a leaving group, and individually a —COOH, —I, —NR₂, —N⁺R₃, —SR, —SO₂R, wherein R is an alkyl, a fluorinated alkyl, aromatic or fluorinated aromatic group, and
Y is a leaving group, and individually a —Cl, —Br, —I, —NR₂, —N⁺R₃, —SR, —SO₂R, or —OR, wherein R is an alkyl, a fluorinated alkyl, aromatic or fluorinated aromatic group

33. The UV reactor subsystem of claim 32, wherein a bonding energy between the leaving group (“(BE)_{L}”) and a core group of the precursor is less than 75 Kcal/Mole, and the range of the (BE)_{L} is about 20 to 45 Kcal/Mole lower than a bonding energy of a next weakest chemical bond energy (“(BE)_{c}”) present in the precursor.

34. The UV reactor subsystem of claim 32, wherein the leaving group is a halide.

35. The UV reactor subsystem of claim 34, wherein the halide is Br.

36. The UV reactor subsystem of claim 34, wherein the halide is I.

37. The UV reactor subsystem of claim 34, wherein the halide is Cl.

38. The UV reactor subsystem of claim 20, wherein the VFC delivers about 0.1 to 1000 square centimeters (“sccm”) of precursor to a deposition system.

39. The UV reactor subsystem of claim 20, wherein the VFC delivers about 2 to 10 square centimeters (“sccm”) of precursor to a deposition system.
